(19) United States
(12) Patent Application Publication
(10) Pub. No.: US 2024/0047945 A1
(43) Pub. Date: Feb. 8, 2024

(54) MULTIWAVELENGTH LASER DEVICE

(71) Applicant: Mitsubishi Electric Corporation, Tokyo (JP)

(72) Inventor: Kei MASUYAMA, Tokyo (JP)

(73) Assignee: Mitsubishi Electric Corporation, Tokyo (JP)

(21) Appl. No.: 18/379,369

(22) Filed: Oct. 12, 2023

Related U.S. Application Data
(63) Continuation of application No. PCT/JP2021/019344, filed on May 21, 2021.

(51) Int. Cl. H01S 5/14; G02F 1/21; G02F 1/225; G02B 6/12; G02F 1/01

(52) U.S. Cl. CPC H01S 5/142; G02F 1/212; G02F 1/225; G02B 6/12007; G02B 6/12004; G02F 1/0147

(57) ABSTRACT

A Mach-Zehnder switch in a multiwavelength laser device is capable of adjusting the output branching ratio between multiwavelength light output from a first input port to a gain unit and multiwavelength light output from a second input port to an output waveguide path, by changing the phase difference between multiwavelength light passing through a first waveguide path and multiwavelength light passing through a second waveguide path.

### CROSS REFERENCE TO RELATED APPLICATIONS

This application is a Continuation of PCT International Application No. PCT/JP2021/019344, filed on May 21, 2021, which is hereby expressly incorporated by reference into the present application.

### TECHNICAL FIELD

The present disclosure relates to a multiwavelength laser device.

### BACKGROUND ART

In order to implement large-capacity optical transmission in an optical communication system, in wavelength division multiplexing (WDM) technology, a plurality of optical signals having different wavelengths is bundled in one optical fiber, so that the plurality of optical signals is transmitted by the one optical fiber.

As an example of the WDM technology, Patent Literature 1 describes a multiwavelength laser device of an external resonator type. The multiwavelength laser device includes a semiconductor gain chip, and an external resonator including two mirrors arranged in such a way as to sandwich the semiconductor gain chip, the external resonator amplifying light by confining the light between the two mirrors. In the external resonator, a cyclic wavelength filter that extracts multiwavelength light having cyclic peak wavelengths from the confined light, and a wavelength spectral filter that outputs a plurality of optical signals by dividing the multiwavelength light for each wavelength are arranged.

### CITATION LIST

### Patent Literature

Patent Literature 1: JP 2018-85475 A

### SUMMARY OF INVENTION

### Technical Problem

In the external resonator as described above, in order to extract amplified multiwavelength light from the external resonator, there are cases where a directional coupler for extracting the multiwavelength light from a waveguide path in the external resonator is used. However, because the directional couplers have wavelength dependence, there is a problem that output of each peak wavelength in the multiwavelength light extracted by the directional coupler varies depending on the corresponding wavelength.

The present disclosure has been made to solve the above problem and provides technology capable of extracting multiwavelength light having constant output for each peak wavelength from an external resonator.

### Solution to Problem

A multiwavelength laser device according to the present disclosure includes: an external resonator to amplify light, and a first output waveguide path to output the light amplified by the external resonator, the multiwavelength laser device including: a semiconductor gain chip; a first Mach-Zehnder switch having a first input port, a second input port, a first output port, a second output port, a first waveguide path optically coupling the first input port and the first output port, and a second waveguide path optically coupling the second input port and the second output port, the first input port optically coupled to the semiconductor gain chip, and the second input port optically coupled to the first output waveguide path; a cyclic wavelength mirror of a ring resonator type to output multiwavelength light having cyclic peak wavelengths to the first Mach-Zehnder switch by partially reflecting light input from the first Mach-Zehnder switch, the cyclic wavelength mirror optically coupled to the first output port and the second output port of the first Mach-Zehnder switch; and a reflector to reflect light having passed through the semiconductor gain chip toward the semiconductor gain chip, the reflector forming the external resonator together with the semiconductor gain chip and the cyclic wavelength mirror by being disposed on a side opposite to a side of the first Mach-Zehnder switch with respect to the semiconductor gain chip, in which the first Mach-Zehnder switch is capable of adjusting an output branching ratio between multiwavelength light output from the first input port to the semiconductor gain chip and multiwavelength light output from the second input port to the first output waveguide path, by changing a phase difference between multiwavelength light passing through the first waveguide path and multiwavelength light passing through the second waveguide path.

### Advantageous Effects of Invention

According to the present disclosure, multiwavelength light having constant output for each peak wavelength can be extracted from the external resonator.

### BRIEF DESCRIPTION OF DRAWINGS

FIG. 1 is a block diagram illustrating a configuration of a multiwavelength laser device 100 according to a first embodiment.

FIG. 2 is a schematic diagram illustrating the configuration of the multiwavelength laser device 100 according to the first embodiment.

FIG. 3 is a diagram illustrating a different multiwavelength laser device having a configuration different from that of the multiwavelength laser device 100 according to the first embodiment.

FIG. 4 is a graph illustrating series transmission characteristics of a ring resonator of a Si fine wire waveguide and a loop mirror in the different multiwavelength laser device illustrated in FIG. 3.

FIG. 5 is a graph illustrating transmission characteristics of multiwavelength light from a first input port to a second input port of a Mach-Zehnder switch in the Mach-Zehnder switch and a cyclic wavelength mirror of a ring resonator type of the multiwavelength laser device according to the first embodiment.

FIG. 6 is a block diagram illustrating a configuration of a multiwavelength laser device according to a second embodiment.

FIG. 7 is a schematic diagram illustrating the configuration of the multiwavelength laser device according to the second embodiment.

FIG. 8 is a schematic diagram illustrating a configuration of a multiwavelength laser device according to a third embodiment.

### DESCRIPTION OF EMBODIMENTS

To describe the present disclosure further in detail, embodiments for carrying out the present disclosure will be described below along with the accompanying drawings.

### First Embodiment

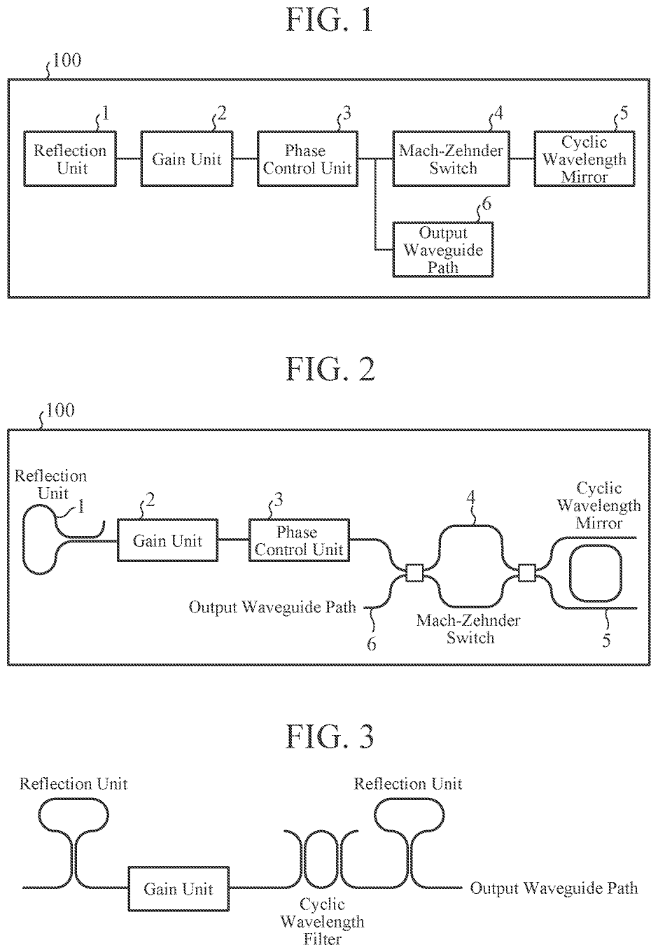

FIG. 1 is a block diagram illustrating a configuration of a multiwavelength laser device 100 according to a first embodiment. FIG. 2 is a schematic diagram illustrating a configuration of the multiwavelength laser device 100 according to the first embodiment. As illustrated in FIGS. 1 and 2, the multiwavelength laser device 100 includes a reflection unit 1, a gain unit 2, a phase control unit 3, a Mach-Zehnder switch 4 (first Mach-Zehnder switch), a cyclic wavelength mirror 5, and an output waveguide path 6.

The multiwavelength laser device 100 includes an external resonator that amplifies light, and the output waveguide path 6 (first output waveguide path) that outputs the light amplified by the external resonator. The external resonator includes the reflection unit 1, the gain unit 2, and the cyclic wavelength mirror 5.

More specifically, the multiwavelength laser device 100 includes the cyclic wavelength mirror 5 in the external resonator, and is a multiwavelength laser device of an external resonator type which can oscillate at multiple wavelengths simultaneously. Note that, in FIGS. 1 and 2, a multiwavelength laser that simultaneously oscillates signal light having N wavelengths (λ₁ to λ_{N}) is illustrated as an example (N is a positive integer equal to or greater than 2). In the multiwavelength laser device 100, the gain unit 2 is disposed between the reflection unit 1 and the cyclic wavelength mirror 5. In the multiwavelength laser device 100, the phase control unit 3 and the Mach-Zehnder switch 4 are arranged in series between the gain unit 2 and the cyclic wavelength mirror 5.

The gain unit 2 is a semiconductor gain chip. More specifically, the gain unit 2 is, for example, a quantum dot gain chip including a quantum dot gain medium.

The reflection unit 1 is disposed on the side opposite to the Mach-Zehnder switch 4 side with respect to the gain unit 2, thereby forming the external resonator together with the gain unit 2 and the cyclic wavelength mirror 5. The reflection unit 1 reflects light having passed through the gain unit 2 toward the gain unit 2.

For example, in a case where the gain unit 2 is a quantum dot gain chip, the reflection unit 1 may be a cleaved end face of the quantum dot gain chip. However, as the gain unit 2, for example, an end face coated with a highly reflective film is more preferable than such a cleaved end face. The gain unit 2 may be a waveguide path element such as a loop mirror or a DBR mirror.

The phase control unit 3 is disposed between the gain unit 2 and the Mach-Zehnder switch 4. The phase control unit 3 controls the phase of multiwavelength light that passes through the phase control unit. More specifically, the phase control unit 3 is an element that gives a phase shift to an optical waveguide path by a thermo-optical effect or the like. Note that the multiwavelength laser device 100 may not include the phase control unit 3, however, it is preferable that the multiwavelength laser device 100 includes the phase control unit 3 because it is expected to improve the stability of the oscillation wavelengths of the external resonator type laser.

The Mach-Zehnder switch 4 includes a first input port, a second input port, a first output port, a second output port, a first waveguide path optically coupling the first input port, and a second waveguide path optically coupling the second input port and the second output port. That is, the Mach-Zehnder switch 4 is a Mach-Zehnder type switch including 2×2 input and output ports.

The first input port of the Mach-Zehnder switch 4 is optically coupled to the gain unit 2. More specifically, in the first embodiment, the first input port of the Mach-Zehnder switch 4 is optically coupled to the gain unit 2 via the phase control unit 3. The second input port of the Mach-Zehnder switch 4 is optically coupled to the output waveguide path 6.

The cyclic wavelength mirror 5 is optically coupled to the first output port and the second output port of the Mach-Zehnder switch 4. The cyclic wavelength mirror 5 outputs multiwavelength light having cyclic peak wavelengths to the Mach-Zehnder switch 4 by partially reflecting light input from the Mach-Zehnder switch 4.

More specifically, in the first embodiment, the cyclic wavelength mirror 5 is an element that reflects only light having cyclic peak wavelengths. The cyclic wavelength mirror 5 includes a 1×2 optical coupler and a ring resonator. Note that the cyclic wavelength mirror 5 may include a 2×2 optical coupler and a ring resonator. Two waveguide paths branching by the 1×2 optical coupler are each arranged in such a way as to be close to the ring resonator. The free spectral range (FSR) of the ring resonator of the cyclic wavelength mirror 5 is designed in such a way as to match a wavelength interval of a desired WDM communication standard. In addition, a heater or the like is disposed on the waveguide path of the ring resonator in the cyclic wavelength mirror 5. By this means, the cyclic wavelength mirror 5 is configured in such a way as to be able to adjust the wavelength interval of the cyclic peak wavelengths of the reflected multiwavelength light by changing the refractive index of the waveguide path by the thermo-optical effect.

Hereinafter, the function of the Mach-Zehnder switch 4 will be described in more detail. The Mach-Zehnder switch 4 can adjust the output branching ratio between multiwavelength light output from the first input port to the gain unit 2 and multiwavelength light output from the second input port to the output waveguide path 6, by changing the phase difference between the multiwavelength light passing through the first waveguide path and the multiwavelength light passing through the second waveguide path.

More specifically, in the first embodiment, the Mach-Zehnder switch 4 can control the output branching ratio to the output waveguide path 6 at a desired branching ratio, by providing a phase difference between the first waveguide path and the second waveguide path by a thermo-optical effect or the like.

For example, in a Si fine wire waveguide, optical coupling can be performed at a desired branching ratio by using a simple directional coupler, however, the directional coupler has wavelength dependence in principle, and the output of each peak wavelength in the multiwavelength light extracted by the directional coupler varies depending on the corresponding wavelength. Meanwhile, in the Mach-Zehnder switch 4, even when a directional coupler having wavelength dependence is used in an input and output unit, the wavelength dependence is reduced with respect to the multiwavelength light output from the second input port to the output waveguide path 6. The internal loss of the external resonator can be varied by adjusting the output branching ratio of the Mach-Zehnder switch 4. However, in order to reduce the power consumption for adjusting the output branching ratio of the Mach-Zehnder switch 4, the Mach-Zehnder switch 4 is preferably designed in such a way as to have an output branching ratio of a desired value when no power is applied.

Hereinafter, the operation of the multiwavelength laser device 100 according to the first embodiment will be described. When a current is applied to the gain unit 2, light having a wavelength corresponding to the FSR of the ring resonator of the cyclic wavelength mirror 5 resonates between the cyclic wavelength mirror 5 and the reflection unit 1, whereby light having a wavelength at which a gain exceeding the internal loss is obtained is output from the second input port of the Mach-Zehnder switch 4 to the output waveguide path 6. At this point, because light other than light having wavelengths at a constant interval Δλ is transmitted through the cyclic wavelength mirror 5, multiwavelength light having cyclic peak wavelengths at the constant interval Δλ can resonate and oscillate simultaneously.

Then, by adjusting the output branching ratio of the Mach-Zehnder switch 4 by the above method while the multiwavelength light from the output waveguide path 6 is monitored, the internal loss of the external resonator at a desired applied current can be minimized, whereby the output power can be maximized.

In addition, since the above-described wavelength dependence can be reduced by using the cyclic wavelength mirror 5 and the Mach-Zehnder switch 4, it is possible to suppress the variation in the output power for each wavelength of the multiwavelength laser output.

Hereinafter, in order to describe the wavelength dependence reduction effect by the multiwavelength laser device 100 according to the first embodiment, comparison is made with another multiwavelength laser device having a configuration different from that of the multiwavelength laser device 100. FIG. 3 is a diagram illustrating a different multiwavelength laser device having a configuration different from that of the multiwavelength laser device 100 according to the first embodiment.

The different multiwavelength laser device illustrated in FIG. 3 has a configuration in which a gain unit and a cyclic wavelength filter are arranged between two reflection units. The reflection unit on the right side out of the two reflection units in FIG. 3 reflects a part of power of light passing through the cyclic wavelength filter and transmits the remaining power. Therefore, a waveguide path on the opposite side to a waveguide path coupled to the cyclic wavelength filter in the reflection unit functions as an output waveguide path.

For example, in a case where the reflection unit on the right side in FIG. 3 includes a loop mirror using a Si fine wire waveguide path, since a directional coupler of the loop mirror has wavelength dependence, the output of each peak wavelength in multiwavelength light extracted by the directional coupler varies for the corresponding wavelength.

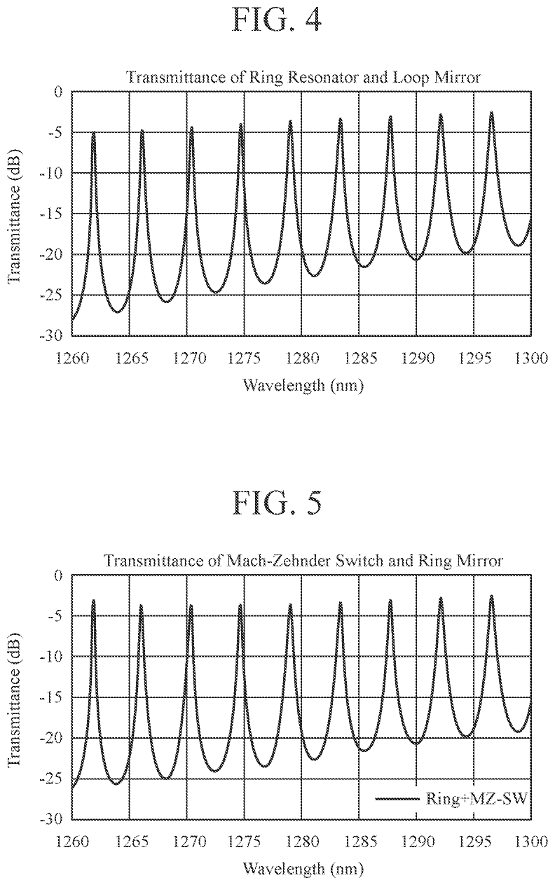

Hereinafter, the transmission characteristics of the different multiwavelength laser device illustrated in FIG. 3 are compared with the transmission characteristics of the multiwavelength laser device 100 according to the first embodiment. Note that it is based on the premise below that a ring resonator of a Si fine wire waveguide path is used as the cyclic wavelength filter of the different multiwavelength laser device illustrated in FIG. 3 and that a loop mirror is used as the reflection unit on the right side in FIG. 3. FIG. 4 is a graph illustrating series transmission characteristics of the ring resonator of the Si fine wire waveguide path and the loop mirror in the different multiwavelength laser device illustrated in FIG. 3. On the other hand, FIG. 5 is a graph illustrating transmission characteristics of multiwavelength light from the first input port to the second input port of the Mach-Zehnder switch 4 in the Mach-Zehnder switch 4 and the cyclic wavelength mirror 5 of the ring resonator type in the multiwavelength laser device 100 according to the first embodiment. Incidentally, in the examples of FIGS. 4 and 5, it is based on the premise that the configurations of the ring resonators are the same, whereby the transmission characteristics are calculated by simulation under the condition that the transmittance of the loop mirror and the branching ratio of the Mach-Zehnder switch are both 50%. In FIGS. 4 and 5, the vertical axis represents the transmittance (dB), and the horizontal axis represents the wavelength (nm).

As can be understood by comparing the graph illustrated in FIG. 4 with the graph illustrated in FIG. 5, in the graph illustrated in FIG. 4, the transmittance increases as it is closer to the longer wavelength side due to the wavelength dependence of the loop mirror, whereas in the graph illustrated in FIG. 5, it can be seen that relatively flat transmission characteristics are obtained. That is, in the multiwavelength laser device 100 according to the first embodiment, multiwavelength light having constant output for each peak wavelength can be extracted from the external resonator.

As described above, the multiwavelength laser device 100 according to the first embodiment includes: the external resonator to amplify light, and the output waveguide path 6 to output the light amplified by the external resonator, the multiwavelength laser device 100 including: the gain unit 2 that is the semiconductor gain chip; the Mach-Zehnder switch 4 having the first input port, the second input port, the first output port, the second output port, the first waveguide path optically coupling the first input port and the first output port, and the second waveguide path optically coupling the second input port and the second output port, the first input port optically coupled to the gain unit 2, and the second input port optically coupled to the output waveguide path 6; the cyclic wavelength mirror 5 to output multiwavelength light having cyclic peak wavelengths to the Mach-Zehnder switch 4 by partially reflecting light input from the Mach-Zehnder switch 4, the cyclic wavelength mirror 5 optically coupled to the first output port and the second output port of the Mach-Zehnder switch 4; and the reflection unit 1 to reflect light having passed through the gain unit 2 toward the gain unit 2, the reflection unit 1 forming the external resonator together with the gain unit 2 and the cyclic wavelength mirror 5 by being disposed on the side opposite to the side of the Mach-Zehnder switch 4 with respect to the gain unit 2, in which the Mach-Zehnder switch 4 is capable of adjusting the output branching ratio between multiwavelength light output from the first input port to the gain unit 2 and multiwavelength light output from the second input port to the output waveguide path 6 by changing the phase difference between multiwavelength light passing through the first waveguide path and multiwavelength light passing through the second waveguide path.

According to the above configuration, by adjusting the output branching ratio of the Mach-Zehnder switch 4, multiwavelength light having constant output for each peak wavelength can be extracted from the external resonator.

For example, in a case where the multiwavelength laser device described in Patent Literature 1 is used for WDM transmission, the oscillation characteristics need to be within a wavelength grid defined by the standard. In multiwavelength laser devices of the related art that can simultaneously oscillate multiwavelength light by disposing a cyclic wavelength filter in an external resonator of a quantum dot laser of an external resonator type, the central wavelength of the cyclic wavelength filter varies due to a manufacturing error. Therefore, it is necessary to control the central wavelength by taking measures such as a temperature control method or a method of applying power to a resistance component formed on the cyclic wavelength filter. Therefore, a wavelength monitoring mechanism for adjusting oscillation wavelengths is essential. In Patent Literature 1, the wavelength spectral filter is disposed in the external resonator in series with the cyclic wavelength filter, and wavelengths are adjusted using light passed through a monitor port provided to the wavelength spectral filter and light passed through a transmission port of the cyclic wavelength filter. However, since the wavelength spectral filter is inserted in the external resonator, there is a disadvantage that the internal loss of the external resonator increases and that, as a result, the output power decreases.

However, according to the configuration of the multiwavelength laser device 100 according to the first embodiment, multiwavelength light having constant output for each peak wavelength can be extracted from the external resonator without increasing the internal loss of the external resonator. It is also possible to monitor and adjust each peak wavelength of the extracted multiwavelength light.

### Second Embodiment

In a second embodiment, a configuration for monitoring the output of each peak wavelength of multiwavelength light will be described.

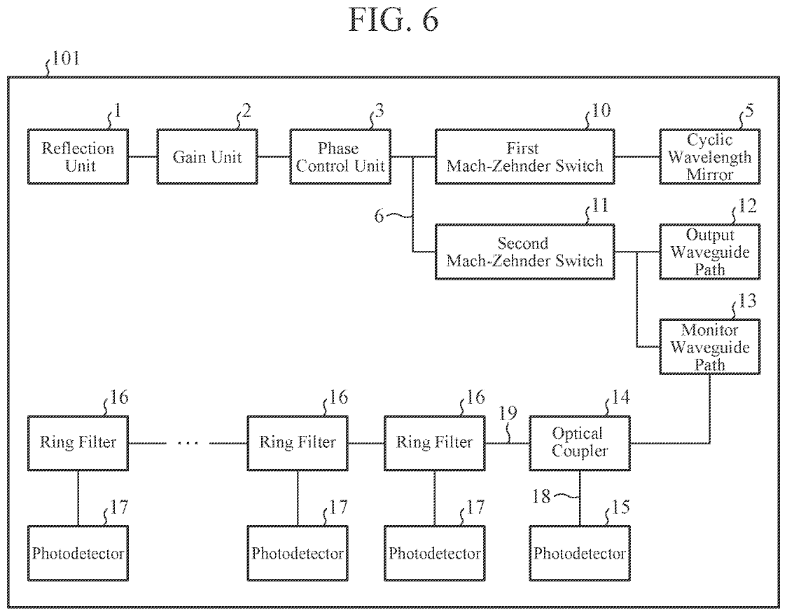

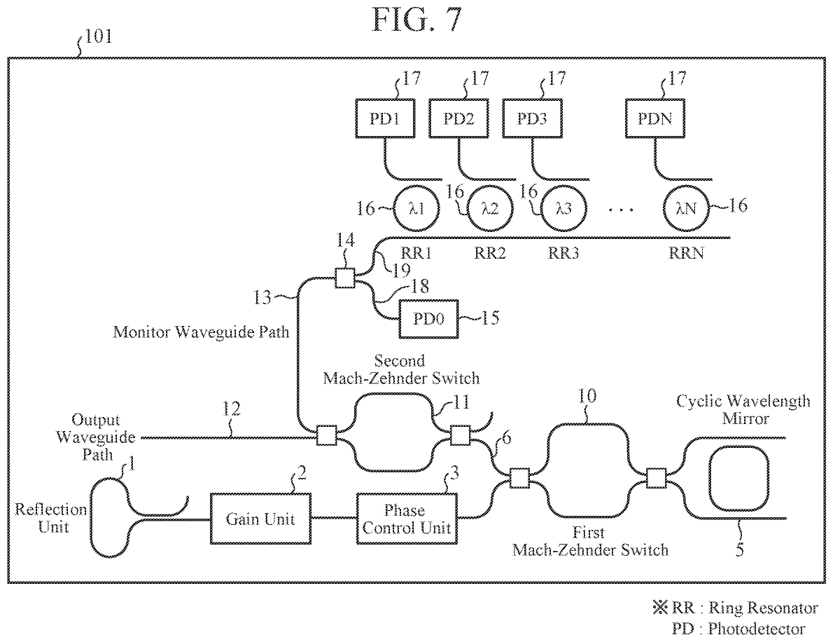

The second embodiment will be described below by referring to drawings. Note that the same symbols are given to components having a similar function as that described in the first embodiment, and description thereof will be omitted. FIG. 6 is a block diagram illustrating a configuration of a multiwavelength laser device 101 according to the second embodiment. FIG. 7 is a schematic diagram illustrating the configuration of the multiwavelength laser device 101 according to the second embodiment. As illustrated in FIGS. 6 and 7, the multiwavelength laser device 101 further includes a second Mach-Zehnder switch 11, an optical coupler 14, a photodetector 15 (first photodetector), a plurality of ring filters 16, and a plurality of photodetectors 17 (plurality of second photodetectors) in addition to the configuration of the multiwavelength laser device 100 according to the first embodiment. Note that the first Mach-Zehnder switch 10 illustrated in FIGS. 6 and 7 has the same function as that of the Mach-Zehnder switch 4 described in the first embodiment.

The multiwavelength laser device 101 according to the second embodiment is a multiwavelength laser device of the external resonator type capable of simultaneously oscillating at multiple wavelengths, the multiwavelength laser device 101 obtained by adding a wavelength monitoring mechanism to the configuration of the multiwavelength laser device 100 according to the first embodiment. The multiwavelength laser device 101 further includes, as waveguide paths, an output waveguide path 12 (second output waveguide path), a monitor waveguide path 13, an output monitor waveguide path 18, and a wavelength monitor waveguide path 19. Note that, in FIGS. 6 and 7, a multiwavelength laser that simultaneously oscillates signal light having N wavelengths (λ₁ to λ_{N}) is illustrated as an example (N is a positive integer equal to or greater than 2).

The second Mach-Zehnder switch 11 includes a first input port, a second input port, a first output port, a second output port, a first waveguide path optically coupling the first input port and the first output port, and a second waveguide path optically coupling the second input port and the second output port. That is, the second Mach-Zehnder switch 11 is a Mach-Zehnder type switch of including 2×2 input and output ports similarly to the first Mach-Zehnder switch 10.

The first input port of the second Mach-Zehnder switch 11 is optically coupled to the first Mach-Zehnder switch 10 via an output waveguide path 6. The first output port of the second Mach-Zehnder switch 11 is optically coupled to the output waveguide path 12. The second output port of the second Mach-Zehnder switch 11 is optically coupled to the monitor waveguide path 13.

The second Mach-Zehnder switch 11 can adjust the output branching ratio between multiwavelength light output from the first output port of the second Mach-Zehnder switch 11 to the output waveguide path 12 and multiwavelength light output from the second output port to the monitor waveguide path 13, by changing the phase difference between the multiwavelength light passing through the first waveguide path of the second Mach-Zehnder switch 11 and the multiwavelength light passing through the second waveguide path of the second Mach-Zehnder switch 11. That is, similarly to the first Mach-Zehnder switch 10, the second Mach-Zehnder switch 11 can control the power of the multiwavelength light output from the output ports at a desired output branching ratio, by giving a phase difference between the first waveguide path and the second waveguide path due to a thermo-optical effect or the like.

The optical coupler 14 has an input port optically coupled to the second Mach-Zehnder switch 11 via the monitor waveguide path 13, a first output port optically coupled to the output monitor waveguide path 18, and a second output port optically coupled to the wavelength monitor waveguide path 19. That is, the optical coupler 14 is a 1×2 optical coupler. The optical coupler 14 branches the multiwavelength light input from the second Mach-Zehnder switch 11 and outputs the multiwavelength light after branching to each of the output monitor waveguide path 18 and the wavelength monitor waveguide path 19.

The photodetector 15 is optically coupled to the optical coupler 14 via the output monitor waveguide path 18. The photodetector 15 detects the multiwavelength light input from the output monitor waveguide path 18.

Each of the plurality of ring filters 16 is optically coupled to the wavelength monitor waveguide path 19. More specifically, in the second embodiment, the plurality of ring filters 16 are N ring resonators, and the wavelength monitor waveguide path 19 is optically coupled in series to the N ring resonators.

Each of the plurality of ring filters 16 extracts light having a predetermined wavelength from the multiwavelength light input from the wavelength monitor waveguide path 19. More specifically, in the second embodiment, the plurality of ring filters 16 is a plurality of ring resonators, and each of the ring resonators is configured in such a manner that a wavelength of light to be extracted conforms to the WDM communication standard, and the wavelength is a drop wavelength (λ₁, λ₂, . . . , or λ_{N}) that is different for each of the ring resonators.

Each of the plurality of photodetectors 17 is coupled to a corresponding ring filter among the plurality of ring filters 16. Each of the plurality of photodetectors 17 detects light extracted by the corresponding ring filter among the plurality of ring filters 16.

Similarly to the first embodiment, the cyclic wavelength mirror 5 according to the second embodiment can adjust the wavelength interval of cyclic peak wavelengths of multiwavelength light output to the first Mach-Zehnder switch 10. More specifically, in the second embodiment, a heater or the like is disposed on a waveguide path of a ring resonator in the cyclic wavelength mirror 5. By this means, the cyclic wavelength mirror 5 is configured in such a way as to be able to adjust the wavelength interval of the cyclic peak wavelengths of the reflected multiwavelength light, by changing the refractive index of the waveguide path by the thermo-optical effect.

Hereinafter, the operation of the multiwavelength laser device 101 according to the second embodiment will be described. When a current is applied to the gain unit 2, light having a wavelength corresponding to the FSR of the ring resonator of the cyclic wavelength mirror 5 resonates between the cyclic wavelength mirror 5 and the reflection unit 1, whereby light having a wavelength at which a gain exceeding the internal loss is obtained is output from the second input port of the first Mach-Zehnder switch 10 to the output waveguide path 6. At this point, since light other than light having wavelengths at a constant interval Δλ is transmitted through the cyclic wavelength mirror 5, multiwavelength light having cyclic peak wavelengths at the constant interval Δλ can resonate and oscillate simultaneously.

The output branching ratio of the second Mach-Zehnder switch 11 is adjusted by the above method, thereby adjusting in such a way that multiwavelength light passes through the monitor waveguide path 13 (bus waveguide path). Next, by monitoring the photodetector 15 and adjusting the branching ratio of the first Mach-Zehnder switch 10 in such a way that the current of the photodetector 15 is maximized, the internal loss of the external resonator is adjusted to one that achieves the maximum output power at a desired applied current. As a result, the output power of the multiwavelength laser device 101 can be maximized. Next, the above wavelength interval in the cyclic wavelength mirror 5 is adjusted in such a way that the oscillation wavelengths of the multiwavelength laser device 101 conform to the WDM standard. Each of the plurality of ring filters 16 optically coupled to the wavelength monitor waveguide path 19 according to the second embodiment is designed in such a way as to drop light having a wavelength conforming to the WDM standard. Therefore, in a case where the cyclic peak wavelengths of the multiwavelength light output from the multiwavelength laser device 101 that is an external resonator type laser conform to the WDM standard, a monitor current of each of the plurality of photodetectors 17 (N photodetectors 17 in FIG. 7) is maximized.

However, usually, a cyclic wavelength interval that defines oscillation wavelengths of a multiwavelength laser of an external resonator type has an offset due to a manufacturing error. Here, by adjusting the refractive index of the ring resonator of the cyclic wavelength mirror 5 by the heater in such a manner as to maximize each monitor current while each of the plurality of photodetectors 17 is monitored, the offset is adjusted in such a way that the wavelength interval of the cyclic peak wavelengths of the multiwavelength light reflected by the cyclic wavelength mirror 5 conforms to the WDM standard.

After the adjustment of the peak wavelengths is completed, outputting the light to the monitor waveguide path 13 is unnecessary, thereby adjusting in such a way that the entire power branches to the output waveguide path 12 by adjusting the output branching ratio of the second Mach-Zehnder switch 11. With the above operation, the multiwavelength laser device 101 that is the external resonator type laser can have oscillation wavelengths conforming to the WDM standard, and the output power of the multiwavelength light output from the multiwavelength laser device 101 can be maximized.

### Third Embodiment

In a third embodiment, a configuration for adjusting the plurality of ring filters 16 described in the second embodiment will be described.

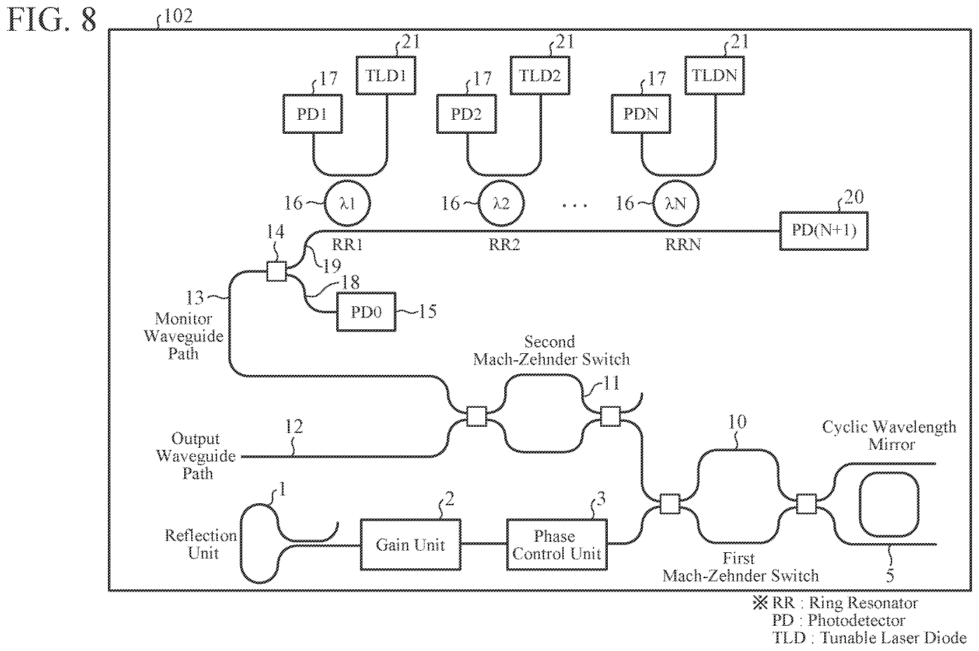

The third embodiment will be described below by referring to drawings. Note that the same symbols are given to components having a similar function as that described in the first embodiment or the second embodiment, and description thereof will be omitted. FIG. 8 is a schematic diagram illustrating the configuration of a multiwavelength laser device 102 according to the third embodiment. As illustrated in FIG. 8, the multiwavelength laser device 102 includes a photodetector 20 (third photodetector) and a plurality of light sources 21 in addition to the configuration of the multiwavelength laser device 101 according to the second embodiment.

The multiwavelength laser device 102 according to the third embodiment has a configuration in which the wavelength monitoring mechanism of the multiwavelength laser device 101 according to the second embodiment is provided with an adjustment mechanism of the ring filters 16 that are ring resonators for wavelength monitoring. In the second embodiment, the description has been given on the case where the ring filters 16 for wavelength monitoring are manufactured as designed, however, in the third embodiment, description will be given on a configuration for adjustment in a case where the drop wavelengths of the ring filters 16 vary due to a manufacturing error or the like. Note that, in FIG. 8, a multiwavelength laser device that simultaneously oscillates signal light having N wavelengths (λ₁ to λ_{N}) is illustrated as an example.

Each of the plurality of light sources 21 is optically coupled to a corresponding ring filter among the plurality of ring filters 16. The plurality of light sources 21 each outputs light of a predetermined wavelength to the corresponding ring filter.

More specifically, in the third embodiment, each of the plurality of light sources 21 is a tunable laser diode (TLD). Each of the plurality of light sources 21 is optically coupled to an end of a waveguide path on the opposite side of an end of the waveguide path coupled to a photodetector 17 of the corresponding ring filter 16 for wavelength monitoring. Here, the coupling between the waveguide path and the light source 21 may be end-face coupling via a fiber or coupling by a grating coupler. In a case where the coupling is achieved by a grating coupler, it is particularly preferable to arrange N grating couplers in an array shape.

The photodetector 20 detects light output from each of the plurality of light sources 21 and extracted by the corresponding ring filter among the plurality of ring filters 16. More specifically, in the third embodiment, the photodetector 20 is optically coupled to the termination of a wavelength monitor waveguide path 19 in which the plurality of ring filters 16 is arranged in series.

Each of the plurality of ring filters 16 according to the third embodiment can adjust the wavelength of light to be extracted. More specifically, in the third embodiment, a heater or the like is disposed on a waveguide path of each of the plurality of ring filters 16. By this means, each of the plurality of ring filters 16 is configured in such a way as to be able to adjust the wavelength of light to be extracted, by changing the refractive index of the waveguide path by the thermo-optical effect.

Hereinafter, the operation of the multiwavelength laser device 102 according to the third embodiment will be described. First, the light source 21 of PD1 in FIG. 8 is caused to output light having a wavelength λ₁ that is desired to be used in the multiwavelength laser device 102, that is, the shortest wavelength (or the longest wavelength) among the wavelengths conforming to the WDM standard, and the light is applied to the ring filter 16 of RR1 in FIG. 8. The light applied to the ring filter 16 of RR1 in FIG. 8 reaches the photodetector 20 via the wavelength monitor waveguide path 19. Then, while heating using a heater of the ring filter 16 of RR1 in FIG. 8, the heater value is adjusted in such a way that a monitor current of the photodetector 20 is maximized.

Next, the light source 21 of PD2 in FIG. 8 is caused to output light having a wavelength λ₂ that is adjacent to the wavelength desired to be used in the multiwavelength laser device 102, that is, the shortest wavelength (or the longest wavelength) λ₁ among the wavelengths conforming to the WDM standard, and the light is applied to the ring filter 16 of RR2 in FIG. 8. The light applied to the ring filter 16 of RR2 in FIG. 8 reaches the photodetector 20 via the wavelength monitor waveguide path 19. Then, while heating using a heater of the ring filter 16 of RR2 in FIG. 8, the heater value is adjusted in such a way that the monitor current of the photodetector 20 is maximized.

By repeating operation similar to the above operation for the wavelength λ₃ to the wavelength λ_{N}, it is possible to adjust the wavelength of light extracted by each ring filter 16 for monitor wavelength (each of the ring filters 16 of RR1 to RRN). After the heater value of each of the ring filters 16 is fixed, the state of the multiwavelength laser device 102 is exactly the same as the state of the multiwavelength laser device 101 according to the second embodiment. Therefore, subsequent operations can be performed as in the second embodiment.

Note that it is possible to include a flexible combination of the embodiments or a modification of any component of the embodiments or to omit any component in the embodiments.

### INDUSTRIAL APPLICABILITY

A multiwavelength laser device according to the present disclosure can extract multiwavelength light having constant output for each peak wavelength from an external resonator, and thus the multiwavelength laser device can be used for technology using multiwavelength light.

### REFERENCE SIGNS LIST

1: reflection unit, 2: gain unit, 3: phase control unit, 4: Mach-Zehnder switch, 5: cyclic wavelength mirror, 6: output waveguide path, 10: first Mach-Zehnder switch, 11: second Mach-Zehnder switch, 12: output waveguide path, 13: monitor waveguide path, 14: optical coupler, 15: photodetector, 16: ring filter, 17: photodetector, 18: output monitor waveguide path, 19: wavelength monitor waveguide path, 20: photodetector, 21: light source, 100, 101, 102: multiwavelength laser device

1. A multiwavelength laser device comprising: an external resonator to amplify light, and a first output waveguide path to output the light amplified by the external resonator, the multiwavelength laser device comprising:
a semiconductor gain chip;
a first Mach-Zehnder switch having a first input port, a second input port, a first output port, a second output port, a first waveguide path optically coupling the first input port and the first output port, and a second waveguide path optically coupling the second input port and the second output port, the first input port optically coupled to the semiconductor gain chip, and the second input port optically coupled to the first output waveguide path;
a cyclic wavelength mirror of a ring resonator type to output multiwavelength light having cyclic peak wavelengths to the first Mach-Zehnder switch by partially reflecting light input from the first Mach-Zehnder switch, the cyclic wavelength mirror optically coupled to the first output port and the second output port of the first Mach-Zehnder switch; and
a reflector to reflect light having passed through the semiconductor gain chip toward the semiconductor gain chip, the reflector forming the external resonator together with the semiconductor gain chip and the cyclic wavelength mirror by being disposed on a side opposite to a side of the first Mach-Zehnder switch with respect to the semiconductor gain chip,
wherein the first Mach-Zehnder switch is capable of adjusting an output branching ratio between multiwavelength light output from the first input port to the semiconductor gain chip and multiwavelength light output from the second input port to the first output waveguide path, by changing a phase difference between multiwavelength light passing through the first waveguide path and multiwavelength light passing through the second waveguide path.

2. The multiwavelength laser device according to claim 1, further comprising a phase controller to control a phase of multiwavelength light that passes through the phase controller, the phase controller disposed between the semiconductor gain chip and the first Mach-Zehnder switch.

3. The multiwavelength laser device according to claim 1, further comprising:
a second output waveguide path;
a monitor waveguide path;
an output monitor waveguide path;
a wavelength monitor waveguide path;
a second Mach-Zehnder switch having a first input port, a second input port, a first output port, a second output port, a first waveguide path optically coupling the first input port and the first output port, and a second waveguide path optically coupling the second input port and the second output port, the first input port optically coupled to the first Mach-Zehnder switch via the first output waveguide path, the first output port optically coupled to the second output waveguide path, and the second output port optically coupled to the monitor waveguide path;
an optical coupler having an input port optically coupled to the second Mach-Zehnder switch via the monitor waveguide path, a first output port optically coupled to the output monitor waveguide path, and a second output port optically coupled to the wavelength monitor waveguide path, the optical coupler to branch multiwavelength light input from the second Mach-Zehnder switch and to output the multiwavelength light after branching to the output monitor waveguide path and the wavelength monitor waveguide path;
a first photodetector optically coupled to the optical coupler via the output monitor waveguide path, the first photodetector to detect the multiwavelength light input from the output monitor waveguide path;
a plurality of ring filters each of which optically coupled to the wavelength monitor waveguide path, each of the plurality of ring filters to extract light of a predetermined wavelength from the multiwavelength light input from the wavelength monitor waveguide path; and
a plurality of second photodetectors each of which to detect light extracted by a corresponding ring filter among the plurality of filtering filters,
wherein the second Mach-Zehnder switch is capable of adjusting an output branching ratio between multiwavelength light output from the first output port of the second Mach-Zehnder switch to the second output waveguide path and multiwavelength light output from the second output port to the monitor waveguide path, by changing a phase difference between multiwavelength light passing through the first waveguide path of the second Mach-Zehnder switch and multiwavelength light passing through the second waveguide path of the second Mach-Zehnder switch.

4. The multiwavelength laser device according to claim 3, wherein the cyclic wavelength mirror is capable of adjusting a wavelength interval of the cyclic peak wavelengths of the multiwavelength light output to the first Mach-Zehnder switch.

5. The multiwavelength laser device according to claim 3, further comprising:
a plurality of light sources each of which to output light having a predetermined wavelength to a corresponding ring filter among the plurality of ring filters, the plurality of light sources each optically coupled to the corresponding ring filter; and
a third photodetector to detect light output by each of the plurality of light sources and extracted by the corresponding ring filter among the plurality of ring filters.

6. The multiwavelength laser device according to claim 5, wherein each of the plurality of ring filters is capable of adjusting a wavelength of light to be extracted.

7. The multiwavelength laser device according to claim 1, wherein the semiconductor gain chip includes a quantum dot gain medium.
